(19) United States
(12) Patent Application Publication
(10) Pub. No.: US 2013/0056738 A1
(43) Pub. Date: Mar. 7, 2013

(54) Method for Manufacturing Thin Film Transistor, Thin Film Transistor and Image Display Apparatus

(71) Applicant: Toppan Printing Co., Ltd., Tokyo (JP)

(72) Inventors: Noriaki Ikeda, Tokyo (JP); Chihiro Imamura, Tokyo (JP); Manabu Ito, Tokyo (JP)

(73) Assignee: Toppan Printing Co., Ltd., Tokyo (JP)

(21) Appl. No.: 13/629,075

(22) Filed: Sep. 27, 2012

Related U.S. Application Data
(63) Continuation of application No. PCT/JP2011/054639, filed on Mar. 1, 2011.

(30) Foreign Application Priority Data
Mar. 30, 2010 (JP) 2010-078573
Mar. 30, 2010 (JP) 2010-078575

(51) Int. Cl. H01L 33/08

(52) U.S. Cl. 257/59; 438/34; 257/72; 257/E33.053

(57) ABSTRACT

A method for manufacturing a thin film transistor includes a first process of forming a gate electrode on a substrate; a second process of forming a gate insulation film so as to cover the gate electrode; a third process of forming a source electrode and a drain electrode on the gate insulation film; a fourth process of forming a semiconductor layer connected to the source electrode and the drain electrode; a fifth process of forming a protection film so as to overlap a portion of the source electrode and the drain electrode immediately above the semiconductor layer; and a sixth process of patterning the semiconductor layer using the protection film as a mask.

### CROSS-REFERENCE TO RELATED APPLICATION

This application is a continuation of International Application No. PCT/JP2011/054639, filed Mar. 1, 2011, which is incorporated herein by reference.

### BACKGROUND OF THE INVENTION

1. Field of the Invention

The present invention relates to a technology characterized in a thin film transistor which is used in an image display apparatus, an active matrix substrate and the like, and a manufacturing method of the thin film transistor.

2. Background Art

In recent years, as the image display apparatus, an image display apparatus such as a liquid crystal display apparatus, an electrophoresis display apparatus and an organic electroluminescence display apparatus which applies an active matrix substrate configured of the thin film transistor thereto has been widely used.

In the image display apparatus which applies the active matrix substrate thereto, as disclosed in JP-B-8-16757, amorphous silicon or polycrystalline silicon is mainly used for the semiconductor material of the thin film transistor. In addition, a thin film transistor which uses a metallic oxide for the semiconductor material has been actively developed in recent years.

The thin film transistor is generally configured of a gate electrode, a gate insulation film, a source electrode, a drain electrode and a semiconductor layer, and is produced in a manner such that a conductive material, an insulation material and semiconductor material are deposited and patterned. A commonly used film formation method is a vacuum film formation method such as a chemical vapor deposition method (Chemical Vapor Deposition; CVD method) or a sputtering method. As a patterning method, photolithography is the most common.

In this way, a vacuum film formation process and a photolithography process are commonly used in manufacturing the thin film transistor. The complicated manufacturing process leads to increased manufacturing costs.

### SUMMARY OF THE INVENTION

The present invention is made in consideration of the above-described circumstances, and aims to provide a thin film transistor and an image display apparatus which can be manufactured by reducing and simplifying the number of manufacturing processes.

A first aspect of the present invention is a method for manufacturing a thin film transistor, including:

forming a gate electrode on a substrate;

forming a gate insulation film so as to cover the gate electrode;

forming a source electrode and a drain electrode on the gate insulation film;

forming a semiconductor layer connected to the source electrode and the drain electrode;

forming a protection film so as to overlap a portion of the source electrode and the drain electrode immediately above the semiconductor layer; and

patterning the semiconductor layer using the protection film as a mask.

A second aspect of the present invention is a thin film transistor, including:

a substrate;

a gate electrode and a capacitor electrode that are formed on the substrate at intervals;

a gate insulation film that covers the gate electrode;

a source electrode and a drain electrode that are formed on the gate insulation film at intervals;

a semiconductor layer formed so as to connect the source electrode and the drain electrode;

a protection film that has an isolated island-like pattern and is formed on the semiconductor layer;

an interlayer insulation film formed so as to cover the source electrode; and

a pixel electrode that is formed on the interlayer insulation film and electrically connected to the drain electrode,

wherein the protection film allows the semiconductor layer to form a pattern.

According to the present invention, a protection film formed on a semiconductor layer is formed like an island at intervals and consequently it is possible to pattern the semiconductor layer using the protection film as a mask when etching the semiconductor layer. For that reason, it is unnecessary to perform a process using a photoresist or the like for the patterning of the semiconductor layer and thereby a manufacturing process can be reduced.

In addition, as the protection film is formed of an organic material, it is possible to form the protection film using a printing method. As a result, manufacturing costs can be suppressed.

As the protection film is set to have a layered structure of an inorganic material and organic materials, it is possible to consecutively deposit the protection film formed of the inorganic material, after the film formation of the semiconductor layer. As a result, it is possible to lessen damage to the surface of the semiconductor layer in the manufacturing process.

In addition, according to the present invention, the protection film formed on the semiconductor layer is used as the mask when etching. As a result, since it is possible to reduce a photolithography process or the like for patterning the semiconductor layer, the number of the manufacturing processes in manufacturing the thin film transistor may be reduced and additionally the manufacturing may be simplified.

Herein, since an ink jet method is used, it is possible to easily form a pattern on the protection film which is isolated like an island.

In addition, since a relief printing method is used, it is possible to form the protection film at a low cost and with high throughput.

Furthermore, since the protection film is set to have a layered structure, it is possible to consecutively deposit the protection film after the film formation on the entire surface of the semiconductor layer and it is possible to relieve the damage to aback channel portion of the semiconductor layer.

In addition, since the formation of the protection film as a stripe pattern in parallel to a wiring pattern of the source electrode is suitable for a case where the relief printing method is used, it is possible to form the protection film with alignment precision and a good yield.

### BRIEF DESCRIPTION OF THE DRAWINGS

FIG. 1 is a schematic cross-sectional view illustrating a thin film transistor according to an embodiment of the present invention.

FIG. 2 is a schematic cross-sectional view illustrating approximately one pixel portion of an active matrix substrate according to an embodiment of the present invention.

FIGS. 3A to 3F are explanatory views of a manufacturing method of a thin film transistor according to an embodiment based on the present invention.

FIGS. 4A to 4B are views illustrating a manufacturing method as an example in a case of multi-layers of a protection film according to an embodiment based on the present invention.

FIG. 5 is a schematic plan view illustrating approximately one pixel portion of an active matrix substrate according to a first embodiment of the present invention.

FIG. 6 is a schematic plan view illustrating approximately one pixel portion of an active matrix substrate according to a second embodiment of the present invention.

FIG. 7 is a schematic cross-sectional view illustrating approximately one pixel portion of an active matrix substrate according to a third embodiment of the present invention.

FIG. 8 is a schematic cross-sectional view illustrating approximately one pixel portion of an image display apparatus according to an embodiment of the present invention.

FIG. 9 is a schematic cross-sectional view illustrating approximately one pixel portion of an image display apparatus according to an embodiment of the present invention.

### DETAILED DESCRIPTION OF THE INVENTION

Hereinafter, embodiments of the present invention will be described with reference to the drawings. In addition, in the embodiments, the same configuration elements have the same reference numerals and a repeated description will be omitted in each embodiment.

### Thin Film Transistor

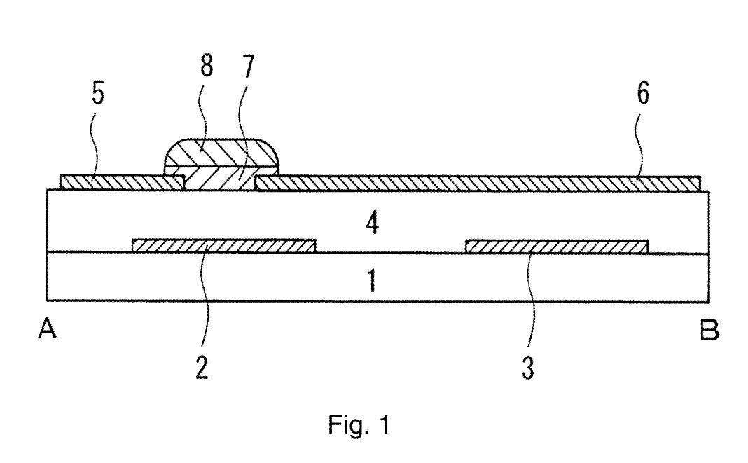

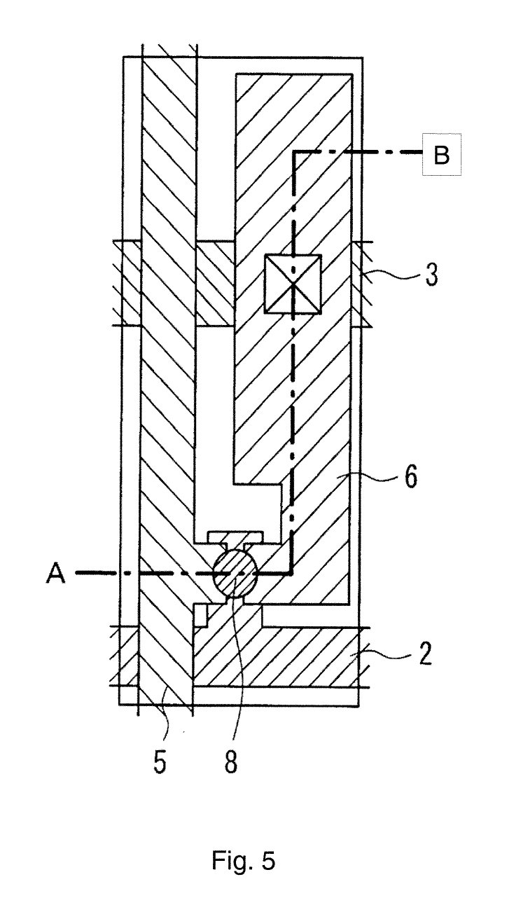

FIG. 1 is a schematic cross-sectional view illustrating a thin film transistor according to an embodiment of the present invention. In addition, FIG. 1 is a cross-sectional view taken along line A-B in FIG. 5.

### Thin Film Transistor

In the thin film transistor of the present embodiment, as illustrated in FIG. 1, a gate electrode 2 and a capacitor electrode 3 are formed on a substrate 1, a gate insulation film 4 is formed so as to cover the gate electrode 2, a source electrode 5 and a drain electrode 6 are formed on the gate insulation film 4, a semiconductor layer 7 is formed so as to be connected to the source electrode 5 and the drain electrode 6, and a protection film 8 is formed on the semiconductor layer 7.

A method for manufacturing the thin film transistor of the present invention includes a first process to a sixth process as follows. That is, a first process of forming a gate electrode 2 on a substrate 1; a second process of forming a gate insulation film 4 which is formed so as to cover the gate electrode 2, on the gate electrode 2; a third process of forming a source electrode 5 and a drain electrode 6 which are formed on the gate electrode 2; a fourth process of forming a semiconductor layer 7 connected to the source electrode 5 and the drain electrode 6; a fifth process of forming a protection film 8 immediately above the semiconductor layer 7; and a sixth process of patterning the semiconductor layer 7 using the protection film 8 as a mask are provided.

### Active Matrix Substrate

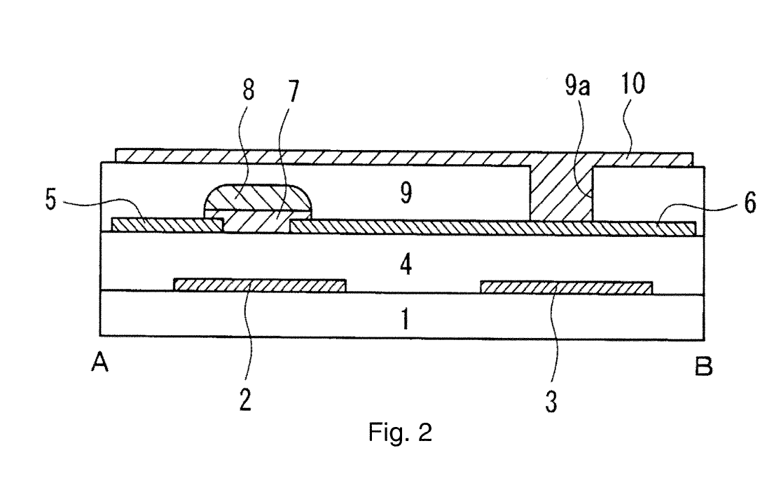

In addition, FIG. 2 is a schematic cross-sectional view illustrating approximately one pixel portion of an active matrix substrate according to an embodiment of the present invention.

A method for manufacturing the active matrix substrate of the present embodiment includes a seventh process of forming an interlayer insulation film 9 and an eighth process of forming a pixel electrode 10, in addition to the first to the sixth processes which are processes for manufacturing the thin film transistor. The active matrix substrate is formed by forming the thin film transistor on the substrate in a matrix form.

### Method for Manufacturing Thin Film Transistor

Hereinafter, a method for manufacturing of the thin film transistor and a method for manufacturing the active matrix substrate of the present embodiment will be described in detail along the processes.

As the substrate 1 according to the present embodiment, polymethyl methacrylate, polyacrylate, polycarbonate, polystyrene, polyethylene sulfide, polyolefin, polyethylene terephthalate, polyethylene naphthalate, cycloolefin polymer, polyether sulfone, triacetylcellulose, polyvinyl fluoride film, ethylene-tetrafluoroethylene copolymer resin, weather resistant polyethylene terephthalate, weather resistant polypropylene, glass fiber reinforced acrylic resin film, glass fiber reinforced polycarbonate, transparent polyimide, fluorine-based resin, cyclic polyolefin-based resin, glass, quartz and the like can be used. The substrate 1 of the present invention is not limited thereto. Although these may be used alone, a combination substrate 1 which has two or more types layered thereon can be used.

In a case where the substrate 1 according to the present embodiment is an organic film, it is preferable to form a transparent gas barrier layer (not illustrated) in order to improve the durability of the thin film transistor. As the gas barrier layer, examples include aluminum oxide (Al₂O₃), silicon oxide (SiO₂), silicon nitride (SiN), silicon oxynitride (SiON), silicon carbide (SiC) and diamond-like carbon (DLC). The present invention is not limited thereto. In addition, it is possible to use the gas barrier layer by laminating two or more layers. The gas barrier layer may be formed on only one surface of the substrate 1 where the organic film is used and may be formed on both surfaces. The gas barrier layer can be formed using a vacuum evaporation method, an ion plating method, a sputtering method, a laser ablation method, a plasma CVD (Chemical Vapor Deposition) method, a hot wire CVD method and a sol-gel method. In addition, the present invention is not limited thereto.

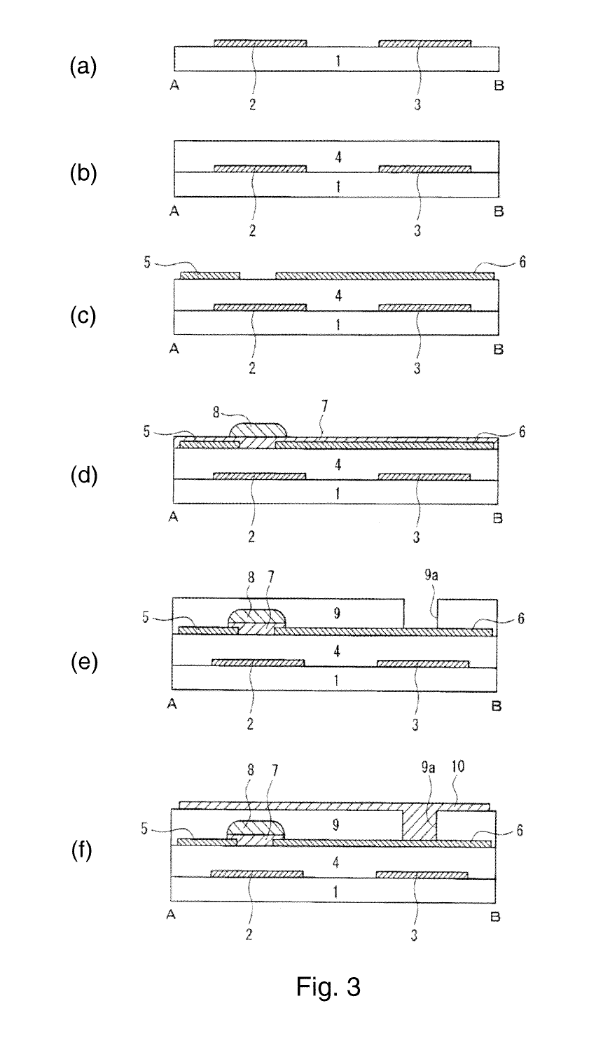

First, as illustrated in FIG. 3A, the gate electrode 2 and the capacitor electrode 3 are formed on the substrate 1. In a case of the active matrix substrate, it is unnecessary to clearly segregate an electrode portion and a wiring portion. In the embodiment, a configuration element of each thin film transistor is specifically referred to as an electrode. In addition, if it is unnecessary to distinguish between the electrode and the wiring, both are collectively referred to as a gate, a capacitor, a source, a drain or the like.

Each electrode (gate electrode 2, capacitor electrode 3, source electrode 5, drain electrode 6 and pixel electrode 10) and the wiring connected to each electrode according to the present embodiment can be formed using a conductive material such as aluminum (Al), copper (Cu), molybdenum (Mo), silver (Ag), chromium (Cr), tungsten (W), gold (Au), platinum (Pt), titanium (Ti) and indium tin oxide (ITO). In addition, these materials maybe used in a single layer, laminated layers or as an alloy.

However, it is more preferable to form the gate, the capacitor, the source and the drain with the same material and layered structure in order to reduce the number of the processes.

Each electrode and the wiring can be formed using the vacuum evaporation method, the ion plating method, the sputtering method, the laser ablation method, the plasma CVD method, a photo-CVD method, the hot wire CVD method, a screen printing method, a relief printing method, an ink jet method and the like. However, without being limited thereto, any general method which is publicly known can be used. For example, there is a method where the film of the conductive material is formed on the entire surface of the substrate, a resist film is formed on a necessary pattern forming portion using the photolithography method thereon and an unnecessary portion is removed by etching, or a method where the patterning is directly formed by a printing method using ink of the conductive material, or the like. However, without being limited thereto, any general patterning method which is publicly known can be used.

Next, as illustrated in FIG. 3B, the gate insulation film 4 is formed. The gate insulation film 4 can be formed on the entire surface of the substrate 1 by removing an outward connecting portion of the gate electrode 2 and the capacitor electrode 3.

As materials used for the gate insulation film 4 according to the present embodiment, examples include inorganic materials such as silicon oxide, silicon nitride, silicon oxynitride, aluminum oxide, tantalum oxide, yttrium oxide, hafnium oxide, hafnium aluminate, zirconium oxide, titanium oxide, or polyacrylate such as PMMA (polymethyl methacrylate), PVA (polyvinyl alcohol), PVP (polyvinyl phenol) and the like. However, the materials are not limited thereto. Resistivity of the insulation material is preferably equal to or more than 10¹¹ Ωcm and more preferably equal to or more than 10¹⁴ Ωcm in order to suppress a gate leakage current.

The gate insulation film 4 is formed depending on the material, appropriately using a vacuum film formation method such as the vacuum evaporation method, the ion plating method, the sputtering method, the laser ablation method, the plasma CVD method, a photo-CVD method, the hot wire CVD method, or a wet film formation method such as a spin coating method, dip coating method and the screen printing method. The gate insulation film 4 may be used as a single layer, two or more layers. In addition, the composition maybe tilted toward the growth direction.

Next, as illustrated in FIG. 3C, the source electrode 5 and the drain electrode 6 are formed. The materials and forming method of the source and the drain are as described above. In addition, the drain electrode 6 is formed in a shape so as to be located immediately above the capacitor electrode 3 as well.

Next, as illustrated in FIG. 3D, the semiconductor layer 7 is formed. The semiconductor layer 7 is deposited so as to connect the source electrode 5 and the drain electrode 6. At this time, the semiconductor layer 7 is formed so as to cover the entire substrate 1.

As the semiconductor layer 7 according to the present embodiment, oxide semiconductor material whose main component is metallic oxide can be used. The oxide semiconductor material is an oxide containing one or more elements among zinc (Zn), indium (In), tin (Sn), tungsten (W), magnesium (Mg) and gallium (Ga). For example, examples include materials such as zinc oxide (ZnO), indium oxide (InO), indium zinc oxide (IN—Zn—O), tin oxide (SnO), tungsten oxide (WO) and gallium indium zinc oxide (In—Ga—Zn—O). The structure of the materials may be any of single crystal, polycrystal, microcrystal, mixed crystal of crystal and amorphous, nanocrystal dispersed amorphous, and amorphous.

The semiconductor layer 7 can be formed using the vacuum film formation method such as the CVD method, the sputtering method, a pulsed laser deposition method and the vacuum evaporation method, the sol-gel method where organometallic is used as precursor or a chemical bath sedimentation method, in addition, the wet film formation method such as a method where a solution obtained by dispersing fine crystal and nanocrystal of the metallic oxide is applied. However, the method is not limited thereto.

Next, as illustrated in FIG. 3D, the protection film 8 is formed. The protection film 8, being formed before an etching process of the semiconductor layer 7, functions as a mask during the etching. That is, since an island-like protection film allows the semiconductor layer 7 to form a pattern, the shapes of the protection film pattern and the semiconductor layer pattern coincide with each other in a final element state.

In general, since the protection film 8 is formed after patterning the semiconductor layer 7, it is necessary to perform a process that the etching is performed by applying the resist which becomes the mask during the etching, on the semiconductor layer 7, and then the resist is stripped. In contrast, in the present embodiment, since the protection film 8 is formed, the patterning process on the semiconductor layer 7 can be omitted and the patterning of the semiconductor layer 7 can be performed without any damage to the semiconductor layer 7.

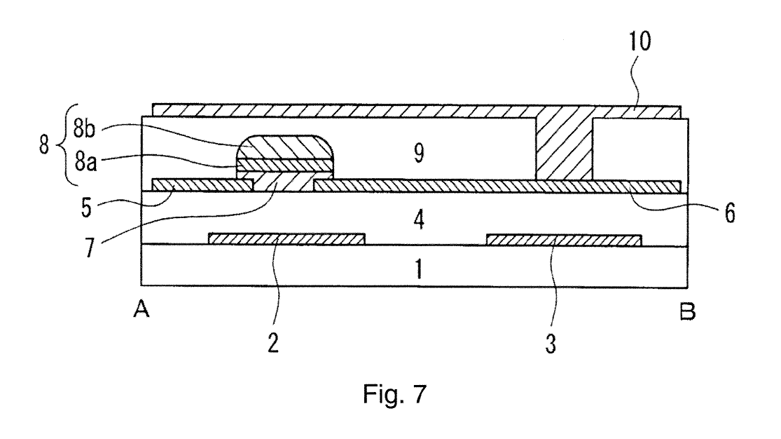

Furthermore, as illustrated in FIG. 7, the protection film 8 can be a multi-layer structure. In this case, an upper protective film 8b is used as an etching stopper or a resist and consequently a lower protection film 8a can be easily patterned. In other words, the organic insulation material which is used as the etching stopper or the resist for patterning the protection film 8a and the semiconductor layer 7 may not be removed and can be used as the protection film 8b.

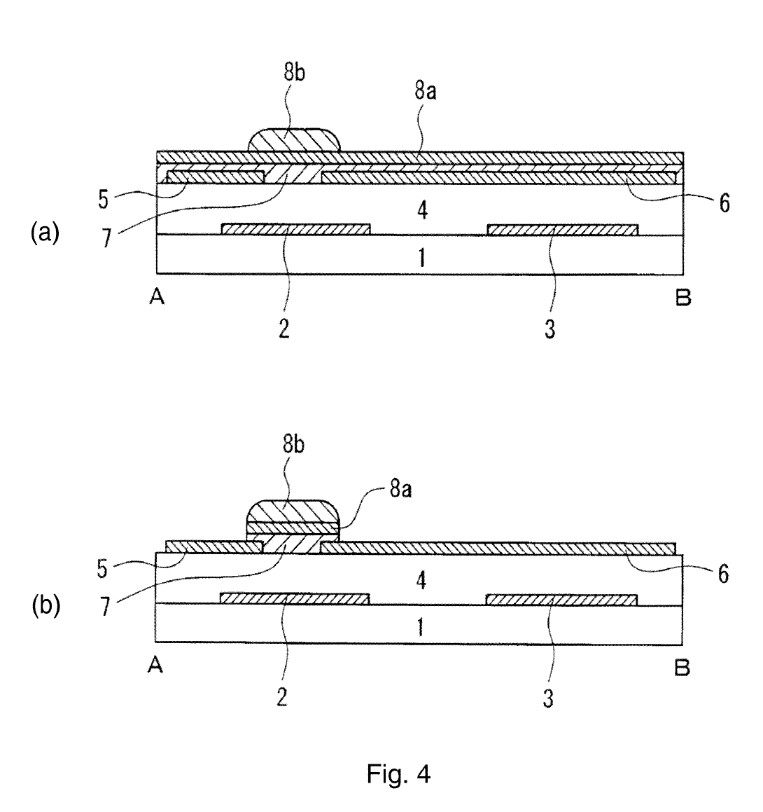

More specifically, as illustrated in FIG. 4A, the lower protection film 8a is formed on the entire surface of the substrate first. Then, the pattern of the upper protection film 8b is formed thereon. Owing to the presence of the protection film 8a, it is possible to avoid deterioration of the semiconductor layer 7 due to developing agent or the etching during the photolithography process, when patterning the protection film 8b.

Next, as illustrated in FIG. 4B, a region of the protection film 8a which is not covered by the protection film 8b can be removed and etching of the semiconductor layer 7 can be continuously performed using the protection film 8b as the etching stopper or the resist. In this case, it is preferable to use the organic insulation material which is easily patterned for the upper protection film 8b. Furthermore, it is preferable to use an inorganic insulation material which has excellent barrier properties and durability, for the lower protection film 8a.

The material for the protection film 8 may preferably have tolerance with respect to an etchant used in patterning the semiconductor layer 7 or sufficient selection ratio during the etching. For example, as the inorganic material, silicon oxide, silicon nitride, silicon oxynitride, aluminum oxide, tantalum oxide, yttrium oxide, hafnium oxide, hafnium aluminate, zirconium oxide, titanium oxide or the like can be used. As the organic material, polyacrylate such as PMMA (polymethyl methacrylate), PVA (polyvinyl alcohol), PVP (polyvinyl phenol), fluorine resin and the like can be used. However, the material is not limited thereto. In addition, the inorganic insulation material maybe mixed with the organic insulation material. Since the protection film 8 does not electrically affect the semiconductor layer 7 of the thin film transistor according to the present invention, the resistivity may be equal to or more than 10¹¹ Ωcm and more specifically equal to or more than 10¹⁴ Ωcm.

The protection film 8 is formed depending on the material, appropriately using a vacuum film formation method such as the vacuum evaporation method, the ion plating method, the sputtering method, the laser ablation method, the plasma CVD method, a photo-CVD method, the hot wire CVD method, or a wet film formation method such as the ink jet method, the relief printing method, the screen printing method, a microcontact printing method. The protection film 8 may be a multi-layer structure in two or more layers using one or multiple manufacturing methods, the materials as described above. Specifically, when the protection film 8 is patterned like the isolated island as illustrated in FIG. 5, the ink jet method or the microcontact printing method can be appropriately used.

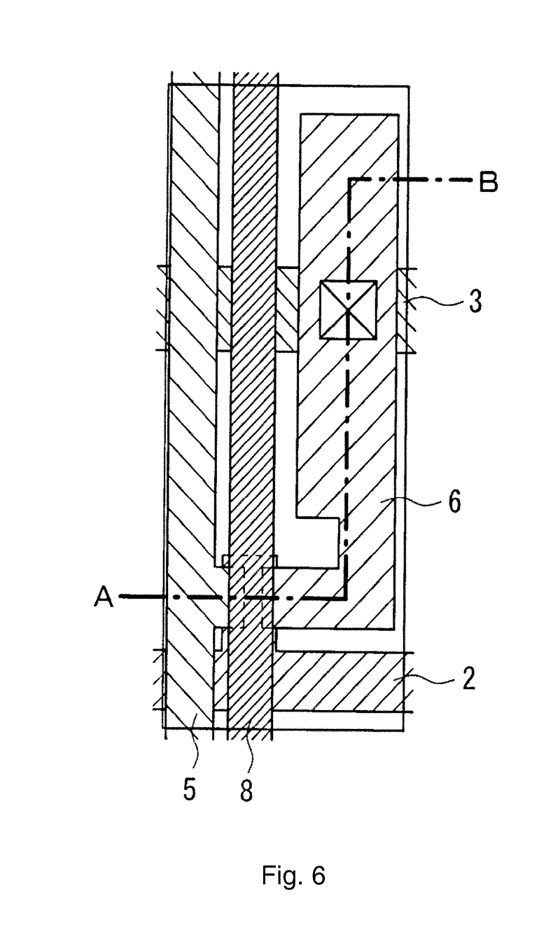

In addition, as illustrated in FIG. 6, when the protection film 8 is patterned in a stripe in parallel to the source electrode 5, the relief printing method can be appropriately used.

Through the above processes, the protection film 8 which has the multi-layer structure can be easily formed. Of course, in this case, as the film of the protection film 8b is further formed in multiple layers, the protection film 8b can also have the multi-layer structure. For example, it is considered that the insulation material which can control the characteristics of the semiconductor layer 7 is used for the layer in contact with the semiconductor layer 7 and the insulation material with high barrier properties is used for the upper layer thereon.

In order to form the active matrix substrate using the thin film transistor according to the present embodiment, as illustrated in FIG. 3F, an interlayer insulation film 9 for insulating the source electrode 5 and a pixel electrode 10 is formed.

The interlayer insulation film 9 according to the present embodiment can be formed using inorganic materials such as silicon oxide, silicon nitride, silicon oxynitride, aluminum oxide, tantalum oxide, yttrium oxide, hafnium oxide, hafnium aluminate, zirconium oxide, titanium oxide, or polyacrylate such as PMMA (polymethyl methacrylate), PVA (polyvinyl alcohol), PS (polystyrene), PVP (polyvinyl phenol) transparent polyimide, polyester, epoxy resin and the like. However, the material is not limited thereto.

In order that the interlayer insulation film 9 may insulate the source electrode 5 and the pixel electrode 10, it is preferable that the resistivity be equal to or more than 10¹¹ Ωcm and more specifically equal to or more than 10¹⁴ Ωcm. The interlayer insulation film 9 may have the same material as the gate insulation film 4 or the protection film 8 or may have a different material. In addition, the interlayer insulation film 9 may be used by layering two or more layers.

The interlayer insulation film 9 is formed depending on the material appropriately using a dry film formation method such as the vacuum evaporation method, the ion plating method, the sputtering method, the laser ablation method, the plasma CVD method, the photo-CVD method, the hot wire CVD method, or the wet film formation method such as a spin coating method, a dip coating method, the screen printing method.

The interlayer insulation film 9 has an opening 9a on the drain electrode 6 and can connect the drain electrode 6 and the pixel electrode 10 via the opening 9a. The opening 9a is provided using a well-known known method such as the photolithography method or the etching, at the same time as or after the formation of the interlayer insulation film 9. Since the interlayer insulation film 9 is used, it is possible to form the pixel electrode on the source electrode 5 as well and consequently an aperture ratio of the image display apparatus can be improved.

Next, a conductive material is subject to film formation on the interlayer insulation film 9, patterned in a predetermined pixel shape and the pixel electrode 10 is formed as illustrated in FIG. 3F. As illustrated in FIG. 2, the pixel electrode is formed on the interlayer insulation film where the opening 9a is formed, such that the drain electrode 6 is exposed. Accordingly, the drain electrode 6 can be electrically connected to the pixel electrode.

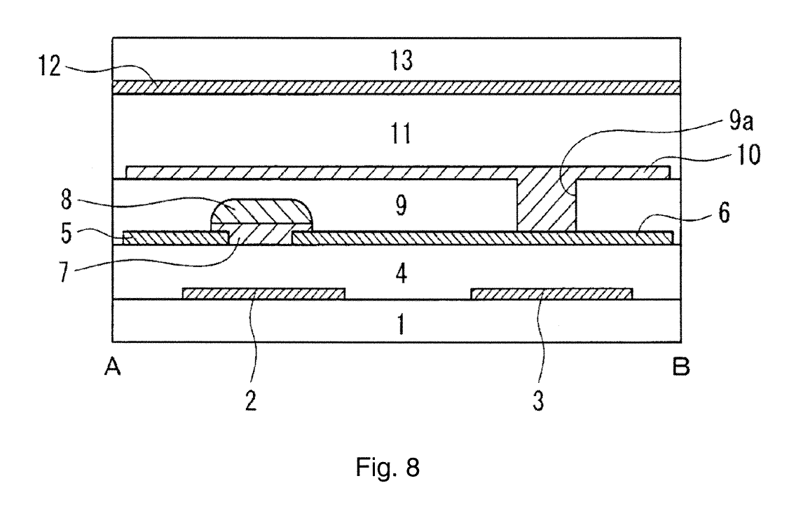

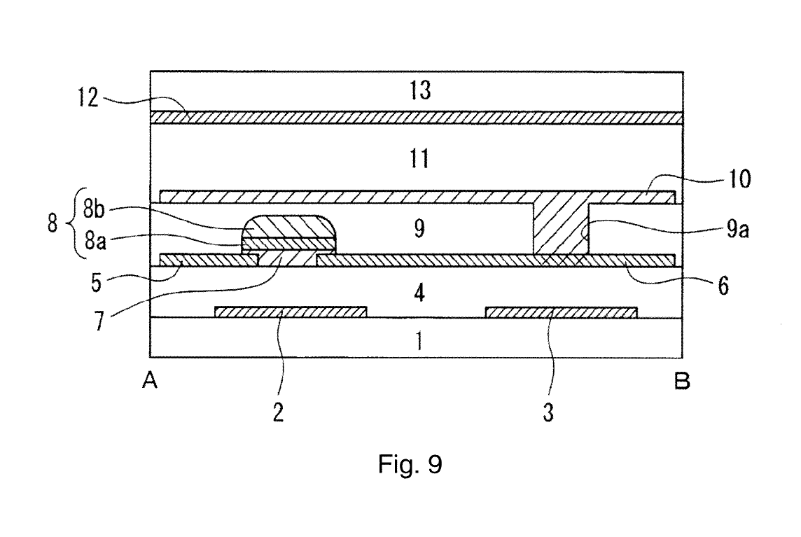

In addition, as illustrated in FIGS. 8 and 9, a display element 11, an opposing electrode 12 and an opposing substrate 13 are provided on the pixel electrode 10 and accordingly the image display apparatus of the present embodiment can be configured.

Examples of the display element include an electrophoresis display medium (electronic paper), a liquid crystal display medium, an organic EL, an inorganic EL or the like. As a laminating method of the display element 11, the opposing electrode 12 and the opposing substrate 13, a method of bonding the laminating body which has the opposing substrate 13, the opposing electrode 12 and the display element 11, on the pixel electrode 10, or a method of sequentially laminating the display element 11, the opposing electrode 12 and the opposing substrate 13 on the pixel electrode 10 may be appropriately selected depending on the kind of display element.

### First Embodiment

As a first embodiment based on the present invention, an active matrix substrate illustrated in FIG. 5 was manufactured.

As a substrate 1, an alkali-free glass EAGLE 2000 made by Corning Incorporated was used. ITO was deposited with a film thickness of 100 nm on the substrate 1 using a DC magnetron sputtering method and a patterning was performed for a desired shape using a photolithography method. More specifically, after applying a photosensitive positive photoresist, exposing and developing by alkaline developing agent was performed, and a resist pattern of a desired shape was formed. Etching was further performed using an ITO etching solution to dissolve the unnecessary ITO. Then, the photoresist was removed using a resist stripping solution and a gate electrode 2 and a capacitor electrode 3 of a desired shape were formed (hereinafter, such a patterning method is referred to as a photolithography method and omitted in description).

Next, on the entire surface other than an outward connecting portion of the gate electrode 2 and the capacitor electrode 3 of the substrate 1 where the gate electrode 2 and the capacitor electrode 3 were formed, silicon nitride (SiN) was deposited with a film thickness of 300 nm to become a gate insulation film 4 using a PECVD method.

In succession, ITO was deposited with a film thickness of 100 nm, using a DC magnetron sputtering method, the patterning was performed for a desired shape using the photolithography method and a source electrode 5 and a drain electrode 6 were formed.

Then, as a semiconductor layer 7, indium gallium zinc oxide (In—Ga—Zn—O) with a film thickness of 40 nm was deposited on the entire surface of the substrate using a RF magnetron sputtering method.

In a region forming a channel portion of a thin film transistor on a semiconductor layer 7 subjected to film formation on the entire surface of the substrate, fluororesin was dropped so as to have an isolated island-like pattern, using an inkjet method, so as to overlap the source electrode 5 and a portion of the drain electrode 6, then baking was performed and a protection film 8 was formed.

Then, the substrate 1 was immersed into 0.1 M hydrochloric acid solution, an unnecessary portion of the semiconductor layer 7 was dissolved using the protection film as a mask, and the patterning was performed for the semiconductor layer 7.

Next, a photosensitive acrylic resin was applied with a film thickness of 3 μm, and exposing, developing and baking were performed to form an interlayer insulation film 9.

ITO was deposited thereon with a film thickness of 100 nm using the DC magnetron sputtering method and the patterning was performed using the photolithography method to forma pixel electrode 10. In this manner, the active matrix substrate of the first embodiment based on the present invention was manufactured.

### Second Embodiment

As a second embodiment based on the present invention, an active matrix substrate illustrated in FIG. 6 was manufactured.

As a substrate 1, an alkali-free glass eagle 2000 made by Corning Incorporated was used. ITO was deposited with a film thickness of 100 nm on the substrate 1 using a DC magnetron sputtering method and a patterning was performed for a desired shape using a photolithography method. More specifically, after applying a photosensitive positive photoresist, exposing and developing by alkaline developing agent were performed, and a resist pattern of a desired shape was formed. Etching was further performed using an ITO etching solution to dissolve the unnecessary ITO. Then, the photoresist was removed using a resist stripping solution and a gate electrode 2 and a capacitor electrode 3 of a desired shape were formed (hereinafter, such a patterning method is referred to as a photolithography method and omitted in description).

Next, on the entire surface other than an outward connecting portion of the gate electrode 2 and the capacitor electrode 3 of the substrate 1 where the gate electrode 2 and the capacitor electrode 3 were formed, silicon nitride (SiN) was deposited with the film thickness of 300 nm to become a gate insulation film 4 using a PECVD method.

In succession, ITO was deposited with a film thickness of 100 nm, using a DC magnetron sputtering method, the patterning was performed for a desired shape using the photolithography method and a source electrode 5 and a drain electrode 6 were formed.

Then, as a semiconductor layer 7, indium gallium zinc oxide (In—Ga—Zn—O) with a film thickness of 40 nm was deposited on the entire surface of the substrate using a RF magnetron sputtering method.

In a region forming a channel portion of a thin film transistor on a semiconductor layer 7 subjected to film formation on the entire surface of the substrate, fluororesin was printed so as to have a strip pattern in parallel to a wiring pattern of a source electrode 5, using a relief printing method, so as to overlap the source electrode 5 and a portion of the drain electrode 6, then baking was performed and a protection film 8 was formed.

Then, the substrate 1 was immersed into 0.1 M hydrochloric acid solution, an unnecessary portion of the semiconductor layer 7 was dissolved using the protection film 8 as a mask, and the patterning was performed for the semiconductor layer 7.

Next, a photosensitive acrylic resin was applied with a film thickness of 3 μm, and exposing, developing and baking were performed to form an interlayer insulation film 9.

ITO was deposited thereon with a film thickness of 100 nm using the DC magnetron sputtering method and the patterning was performed using the photolithography method to form a pixel electrode 10. In this manner, the active matrix substrate of the second embodiment based on the present invention was manufactured.

### Third Embodiment

As a third embodiment based on the present invention, an active matrix substrate illustrated in FIG. 7 was manufactured.

As a substrate 1, an alkali-free glass EAGLE 2000 made by Corning Incorporated was used. ITO was deposited with a film thickness of 100 nm on the substrate 1 using a DC magnetron sputtering method and a patterning was performed for a desired shape using a photolithography method. More specifically, after applying a photosensitive positive photoresist, exposing and developing by alkaline developing agent were performed, and a resist pattern of a desired shape was formed. Etching was further performed using an ITO etching solution to dissolve the unnecessary ITO. Then, the photoresist was removed using a resist stripping solution and a gate electrode 2 and a capacitor electrode 3 of a desired shape were formed (hereinafter, such a patterning method is referred to as a photolithography method and omitted in description).

Next, on the entire surface other than an outward connecting portion of the gate electrode 2 and the capacitor electrode 3 of the substrate 1 where the gate electrode 2 and the capacitor electrode 3 were formed, silicon nitride (SiN) was deposited with a film thickness of 300 nm to form a gate insulation film 4 using a PECVD method.

In succession, ITO was deposited with a film thickness of 100 nm, using a DC magnetron sputtering method, the patterning was performed for a desired shape using the photolithography method and a source electrode 5 and a drain electrode 6 were formed.

Then, as a semiconductor layer 7, indium gallium zinc oxide (In—Ga—Zn—O) with a film thickness of 40 nm was deposited on the entire surface of the substrate using a RF magnetron sputtering method.

In succession, as a lower protection film 8a, SiON film with a film thickness of 80 nm was deposited on the entire surface of the substrate using a RF magnetron sputtering method. In a region forming a channel portion of a thin film transistor on the lower protection film 8a, fluororesin was dropped, using an inkjet method, so as to overlap the source electrode 5 and a portion of the drain electrode 6, baking was performed, and an upper protection film 8b was formed.

Thereafter, using the upper protection film 8b as a mask, etching was performed for an unnecessary portion of the lower protection film 8a by reactive ion etching. Subsequently, the substrate 1 was immersed into 0.1 M hydrochloric acid solution and etching was performed for the unnecessary portion of the semiconductor layer 7.

Next, a photosensitive acrylic resin was applied with a film thickness of 3 μm, and exposing, developing and baking were performed to form an interlayer insulation film 9.

ITO was deposited thereon with a film thickness of 100 nm using the DC magnetron sputtering method, the patterning was performed using the photolithography method and a pixel electrode 10 was formed. In this manner, the active matrix substrate of the third embodiment based on the present invention was manufactured.

As described above, in the method for manufacturing the image display apparatus according to embodiments of the present invention, since the semiconductor layer 7 are patterned using the protection film 8 as the mask, the photolithography process for patterning the semiconductor layer can be reduced and consequently the manufacturing process can be simplified.

What is claimed is:

1. A method for manufacturing a thin film transistor, comprising:
forming a gate electrode on a substrate;
forming a gate insulation film so as to cover the gate electrode;
forming a source electrode and a drain electrode on the gate insulation film;
forming a semiconductor layer connected to the source electrode and the drain electrode;
forming a protection film so as to overlap a portion of the source electrode and the drain electrode immediately above the semiconductor layer; and
patterning the semiconductor layer using the protection film as a mask.

2. The method for manufacturing a thin film transistor according to claim 1,
wherein an ink jet method is used in the forming of the protection film.

3. The method for manufacturing a thin film transistor according to claim 1,
wherein a relief printing method is used in the forming of the protection film.

4. The method for manufacturing a thin film transistor according to claim 1,
wherein the forming of the protection film includes:
forming a first protection film immediately above the semiconductor layer;
forming a second protection film on the first protection film, the second protection film patterned using a printing method; and
patterning the first protection film and the semiconductor layer using the second protection film as the mask.

5. The method for manufacturing a thin film transistor according to claim 1,
wherein the semiconductor layer is formed of a metallic oxide.

6. A thin film transistor that is manufactured by the method according to claim 1.

7. The method for manufacturing a thin film transistor according to claim 1, further comprising:
forming an interlayer insulation film that has an opening which is arranged on the source electrode and the drain electrode, and the opening is formed so as to expose a portion of the drain electrode; and
forming a pixel electrode which is arranged on the interlayer insulation film and is electrically connected to the drain electrode via the opening.

8. The method for manufacturing a thin film transistor according to claim 7,
wherein the forming of the protection film includes forming the protection film so as to have a stripe pattern parallel to the source electrode.

9. The method for manufacturing a thin film transistor according to claim 7,
wherein the forming of the protection film includes forming the protection film so as to have an isolated island-like pattern.

10. A thin film transistor, comprising:
a substrate;
a gate electrode and a capacitor electrode that are formed on the substrate at intervals;
a gate insulation film that covers the gate electrode;
a source electrode and a drain electrode that are formed on the gate insulation film at intervals;
a semiconductor layer formed so as to connect the source electrode and the drain electrode;
a protection film that has an isolated island-like pattern and is formed on the semiconductor layer;
an interlayer insulation film formed so as to cover the source electrode; and
a pixel electrode that is formed on the interlayer insulation film and electrically connected to the drain electrode,
wherein the protection film allows the semiconductor layer to form a pattern.

11. The thin film transistor according to claim 10,
wherein the semiconductor layer is patterned and formed using the protection film as a mask.

12. The thin film transistor according to claim 10,
wherein the semiconductor layer is formed of a metallic oxide.

13. The thin film transistor according to claim 10,
wherein the protection film is formed of an organic material.

14. The thin film transistor according to claim 10,
wherein the protection film includes a first protection film formed of an inorganic material and a second protection film that is formed on an upper side of the first protection film and is formed of an organic material.

15. An image display apparatus,
wherein a display medium, an opposing electrode, and an opposing substrate are provided on the thin film transistor according to claim 10.

16. The image display apparatus according to claim 15,
wherein the display medium is any one among an electrophoresis display medium, a liquid crystal display medium, an organic electroluminescence display medium, and an inorganic electroluminescence display medium.
